(19) United States
(12) Patent Application Publication
(10) Pub. No.: US 2023/0337398 A1
(43) Pub. Date: Oct. 19, 2023

(54) HEAT DISSIPATION MODULE

(71) Applicant: TAIWAN MICROLOOPS CORP., New Taipei City (TW)

(72) Inventor: Chun-Hung LIN, New Taipei City (TW)

(21) Appl. No.: 17/743,261

(22) Filed: May 12, 2022

(30) Foreign Application Priority Data
Apr. 15, 2022 (TW) 111114537

(51) Int. Cl. H05K 7/20

(52) U.S. Cl. CPC H05K 7/20336; H05K 7/2039

(57) ABSTRACT

A heat dissipation module is provided. The heat dissipation module has a heat conductive housing and at least one heat pipe. The heat conductive housing has a first half housing and a second half housing. The first half housing and the second half housing are coupled with each other. A capillary is attached to an internal surface of the heat conductive housing, and the heat conductive housing is filled with a working fluid. The heat pipe penetrates through the heat conductive housing. The heat pipe is attached to an internal surface of a bottom of the first half housing.

### BACKGROUND OF THE DISCLOSURE

### Technical Field

The present disclosure relates to a heat pipe for a heat dissipation, particularly to a heat dissipation module having a vapor chamber structure combined with a heat pipe.

### Description of Related Art

A heat pipe is a component used for dissipating heat generated by an electronic device, and the main function of the heat pipe is to transfer heat. Generally speaking, a part of the heat pipe is used for absorbing heat, and the other part of the heat pipe is used for dissipating heat. The part of the heat pipe used for absorbing heat is often connected to a heat conductive member. The heat conductive member contacts a heat generating source to absorb heat generated by the heat generating source, and then the heat is transferred via the heat pipe to the part of the heat pipe used for dissipating heat to make the heat be dissipated. A vapor chamber is often configured as the above-mentioned heat conductive member, and the part of the heat pipe used for absorbing heat penetrates into the vapor chamber. The heat pipe and an internal surface of the vapor chamber are spaced with an interval to assist a working fluid to circulate in the vapor chamber. The vapor chamber may rapidly dissipate heat from the heat generating source, but only the vaporized working fluid is used as a heat exchanging medium between the heat pipe and the vapor chamber, thus the heat exchanging rate is insufficient, and the heat may be easily accumulated in the vapor chamber.

Accordingly, the applicant of the present disclosure has devoted himself for improving the mentioned disadvantages.

### SUMMARY OF THE DISCLOSURE

The present disclosure is to provide a heat dissipation module having a vapor chamber structure combined with a heat pipe.

Accordingly, the present disclosure provides a heat dissipation module having a heat conductive housing and at least one heat pipe. The heat conductive housing has a first half housing and a second half housing. The first half housing and the second half housing are coupled with each other. A capillary structure is attached to an internal surface of the heat conductive housing and a working fluid is filled in the heat conductive housing. The heat pipe penetrates through the heat conductive housing, and the heat pipe is attached to an internal surface of a bottom of the first half housing.

According to the heat dissipation module of the present disclosure, the first half housing has a pair of first edge notches correspondingly disposed on an edge of an opening thereof, and the heat pipe is embedded in the pair of first edge notches to penetrate through the first half housing; the second half housing has a pair of second edge notches correspondingly disposed on an edge of an opening thereof, and the heat pipe is embedded in the pair of second edge notches to penetrate through the second half housing; and the capillary structure covers an outer surface of the heat pipe.

According to the heat dissipation module of the present disclosure, the heat pipe has a heat absorbing segment, the heat adsorbing segment is disposed in the heat conductive housing, a transversal cross-sectional area of the heat absorbing segment is smaller than the transversal cross-sectional areas of the other segments of the heat pipe; the capillary structure covers the heat absorbing segment, the heat absorbing segment is in a flat shape, and one surface of the heat absorbing segment is attached to an internal surface of the first half housing.

According to the heat dissipation module of the present disclosure, a plurality of heat conductive columns are disposed in the heat conductive housing, two ends of each of the heat conductive columns are connected to the internal surface of the first half housing and an internal surface of the second half housing, the plurality of heat conductive columns and the heat absorbing segment are separately arranged, and the capillary structure covers an outer surface of each of the heat conductive columns.

According to the heat dissipation module of the present disclosure, the heat pipes is multiple in numbers and the heat pipes are disposed and arranged at intervals, a plurality of heat conductive columns are disposed in the heat conductive housing, two ends of each of the heat conductive columns are connected to the internal surface of the first half housing and an internal surface of the second half housing, and the plurality of heat conductive columns are disposed in intervals of the plurality of heat pipes.

According to the heat dissipation module of the present disclosure, the capillary structure covers an outer surface of each of the heat conductive columns.

According to the heat dissipation module of the present disclosure, the heat pipe and an internal surface of a bottom of the second half housing are separately arranged, or the heat pipe is attached to the internal surface of the bottom of the second half housing.

According to the heat dissipation module of the present disclosure, one side of the heat pipe is attached to the first half housing to assist the heat conductive housing to absorb heat.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective view showing a heat dissipation module according to some embodiments of the present disclosure;

FIG. 2 is a perspective exploded view showing the heat dissipation module according to some embodiments of the present disclosure;

FIG. 3 is a transversal cross-sectional view showing the heat dissipation module according to some embodiments of the present disclosure; and

FIG. 4 to FIG. 11 are schematic views showing various alternative states of the heat dissipation module according to some embodiments of the present disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

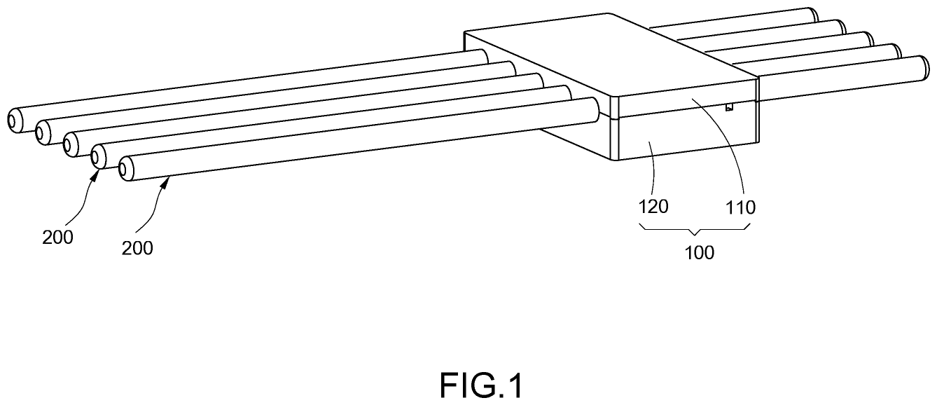

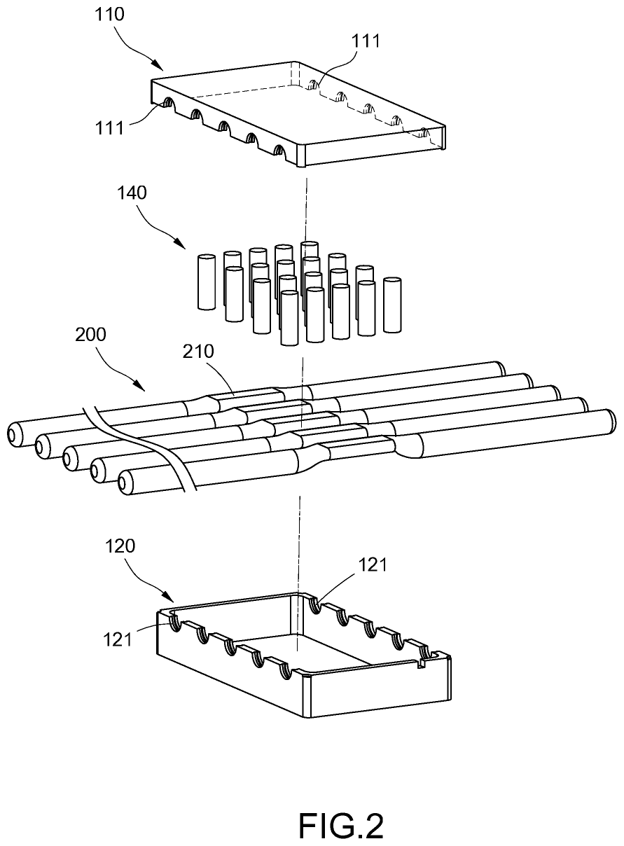

Please refer from FIG. 1 to FIG. 3, the present disclosure is directed to a heat dissipation module having a heat conductive housing 100 and at least one heat pipe 200.

In some embodiments, the heat conductive housing 100 is made of aluminum or copper. The heat conductive housing 100 is in a flat shape. A capillary structure 130 is attached on an internal surface of the heat conductive housing 100. The heat conductive housing 100 is filled with a working fluid (not shown in figures), and the working fluid is a fluid having a low boiling point, such as water or a coolant. The capillary structure 130 may be a copper woven net or copper powders sintered on a thermal housing, and has pores allowing the working fluid to be absorbed. The heat conductive housing 100 is divided into a first half housing 110 and a second half housing 120 along a thickness direction (the top-down direction in the FIG. 1). In some embodiments, a thickness (or depth) of the first half housing 110 is less than a thickness (or depth) of the second half housing 120. The first half housing 110 and the second half housing 120 are both in a flat shape, and one sides of the first half housing 110 and the second half housing 120 are respectively formed as an opening. The opening of the first half housing 110 and the opening of the second half housing 120 are coupled with each other to form a closed inner space. A bottom of the first half housing 110 and a bottom of the second half housing 120 are correspondingly disposed.

In some embodiments, the heat dissipation module has a plurality of heat pipes 200 similar to each other. Each of the heat pipes 200 penetrates through the heat conductive housing 100 from one side at one edge of the heat conductive housing 100 to another side at another edge of the heat conductive housing 100. Substantially speaking, the edge of the opening of the first half housing 110 is respectively formed with a pair of first edge notches 111 corresponding to each of the heat pipes 200. As such, each of the heat pipes 200 is embedded in the pair of first edge notches 111 to penetrate through the first half housing 110. In some embodiments, the edge of the opening of the second half housing 120 is respectively formed with a pair of second edge notches 121 corresponding to each of the heat pipes 200. As such, each of the heat pipes 200 is embedded in the pair of second edge notches 121 to penetrate through the second half housing 120. Because the depth of the first half housing 110 is less than the depth of the second half housing 120, the heat pipe 200 is attached to the internal surface of the bottom of the first half housing 110, and the heat pipe 200 is arrange separately from the internal surface of the bottom of the second half housing 120.

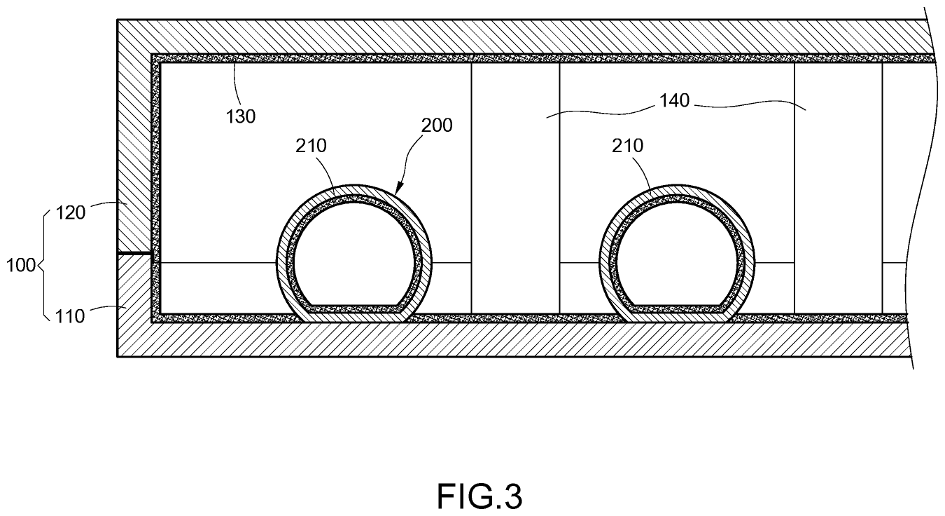

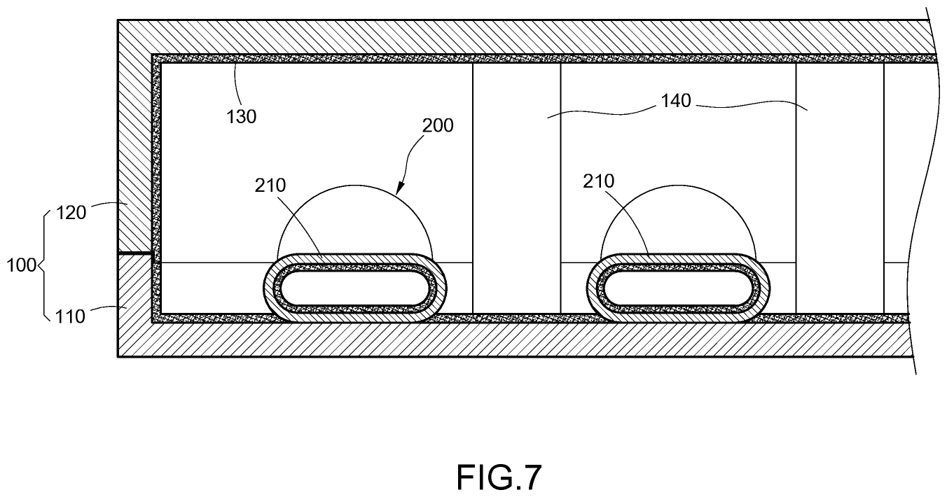

A middle segment of the heat pipe 200 is formed as a heat absorbing segment 210. The heat adsorbing segment 210 is disposed in the heat conductive housing 100. A transversal cross-sectional area of the heat absorbing segment 210 is smaller than the transversal cross-sectional areas of the other segments of the heat pipe 200. At least one side of the heat absorbing segment 210 is squeezed to form a flat surface to be attached to the internal surface of the bottom of the first half housing 110 for assisting the heat conductive housing 100 to absorb heat. As shown in FIG. 3, the heat absorbing segment 210 may be formed as a semi-circular pipe member. Moreover, the first half housing 110 may be attached to a heat generating source to increase the heat exchanging efficiency between the heat conductive housing 100 and the heat generating source. The heat absorbing segment 210 and the internal surface of the bottom of the second half housing 120 may be separately arranged to assist the convection of the vaporized working fluid. Please refer to FIG. 7, the heat absorbing segment 210 may be in a flat shape, one surface of the heat absorbing segment 210 is attached to the internal surface of the first half housing 110, and a wider gap is formed between another surface of the heat absorbing segment 210 and the internal surface of the bottom of the second half housing 120.

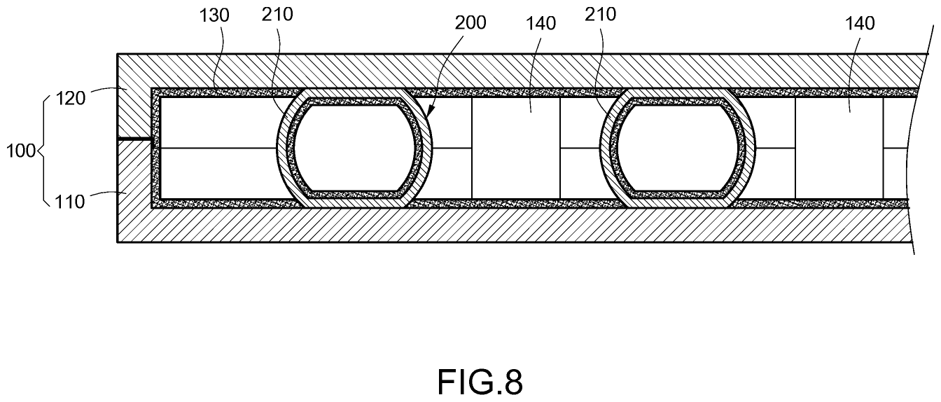

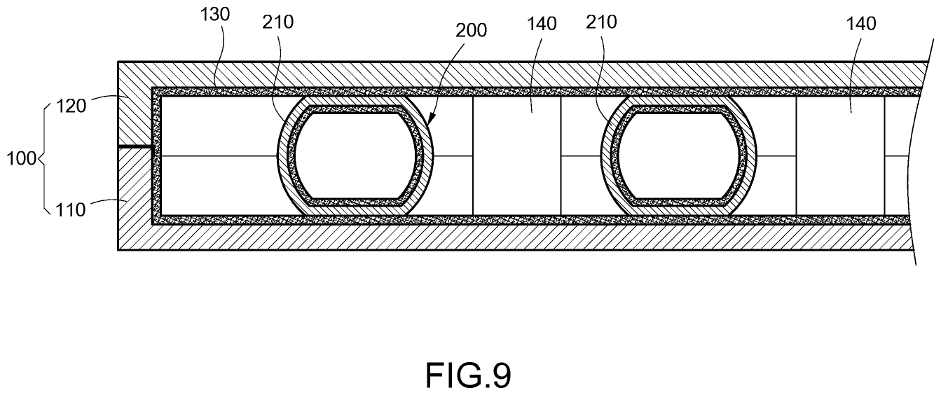

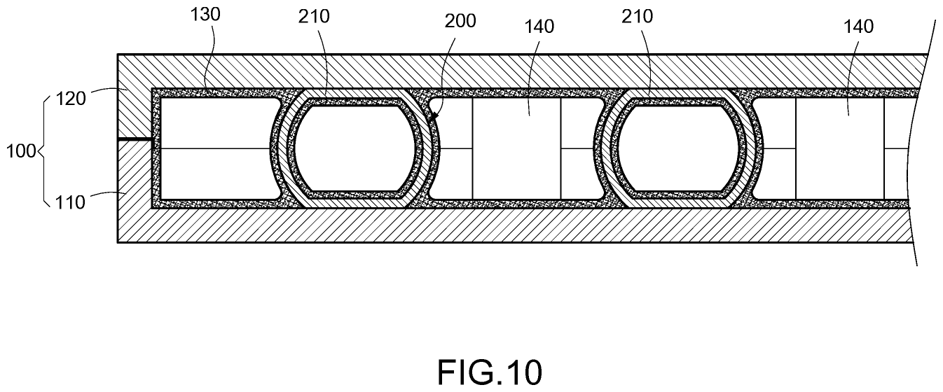

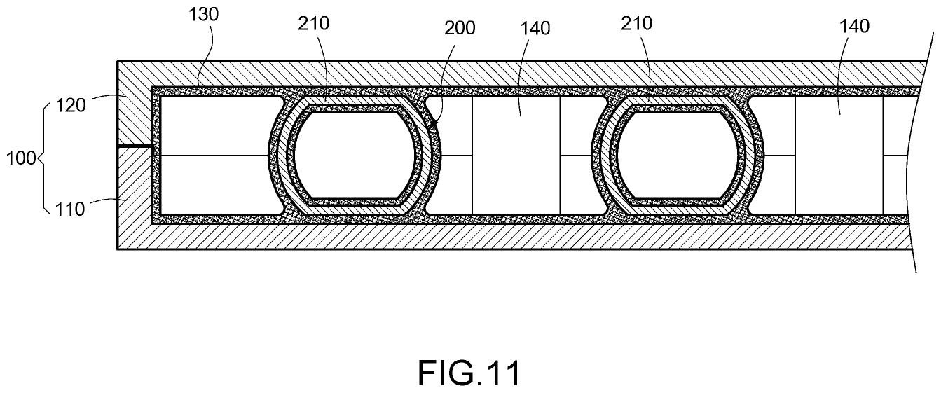

Please refer from FIG. 8 to FIG. 11, the thickness (or depth) of the first half housing 110 may be equal to the thickness (or depth) of the second half housing 120, thus the heat absorbing segment 210 is attached to the internal surface of the bottom of the second half housing 120 to assist the heat conductive housing 100 to absorb heat.

A plurality of heat conductive columns 140 are disposed in the heat conductive housing 100. Two ends of each of the heat conductive columns 140 are connected to the internal surface of the bottom of the first half housing 110 and the internal surface of the bottom of the second half housing 120 to increase the heat transferring efficiency between two surfaces of the heat conductive housing 100. The plurality of heat conductive columns 140 are disposed in intervals of the heat pipes 200 to make the plurality of heat conductive columns 140 and the heat absorbing segment 210 be separately arranged, thus the assembly may be simplified and the convection of the working fluid may be assisted. The capillary structure 130 covers an outer surface of each of the heat conductive columns 140 to increase the heat exchanging area between the working fluid and each of the heat conductive columns 140.

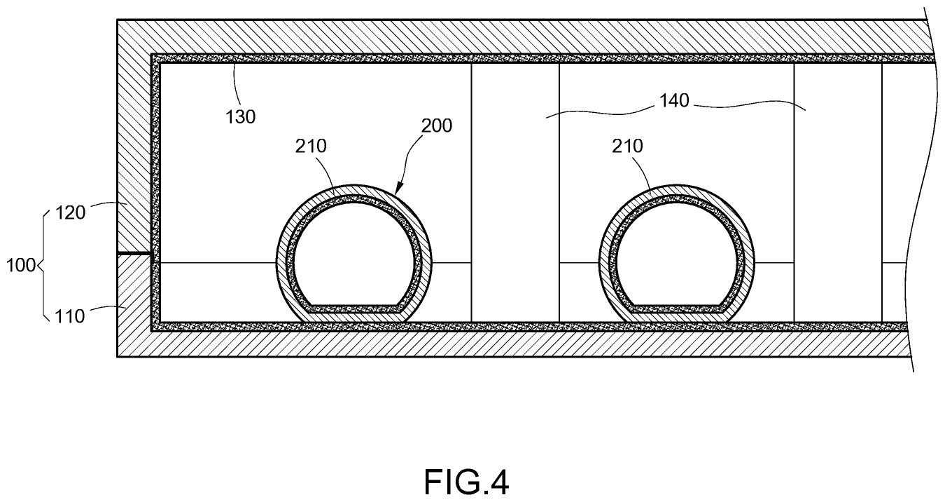

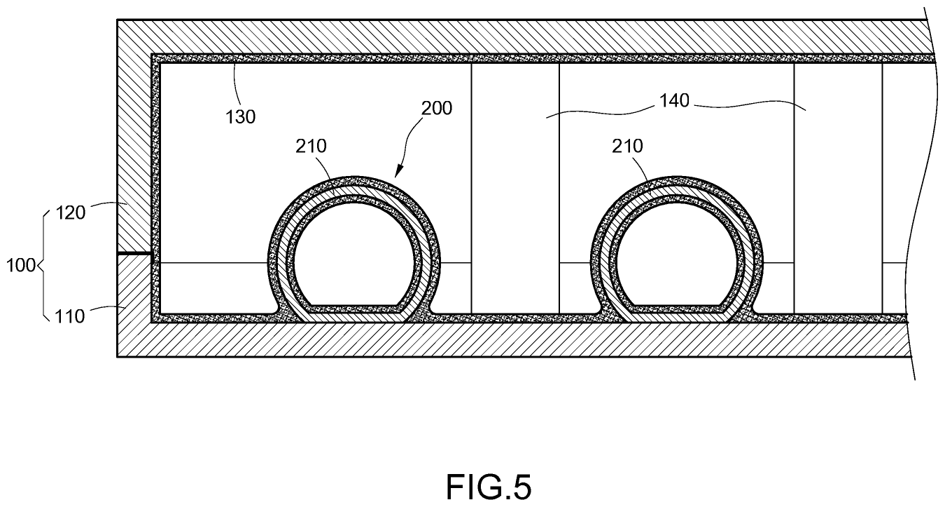

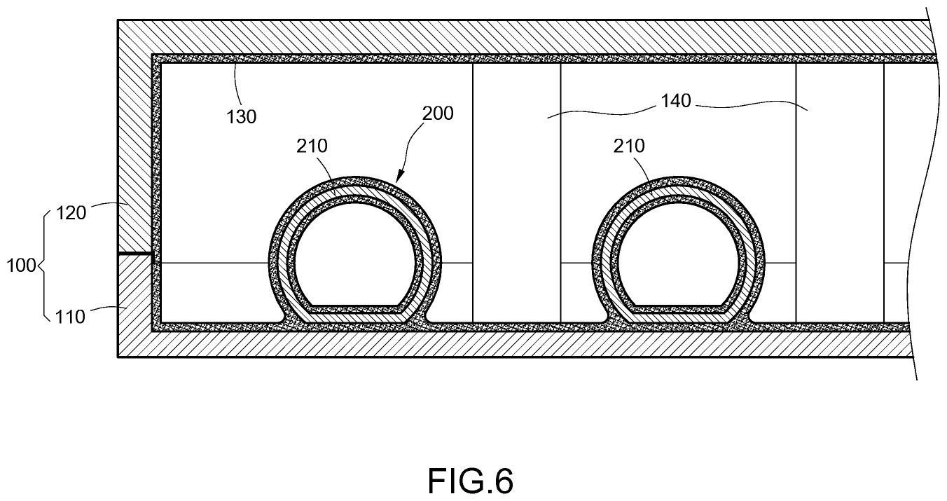

Please refer to FIG. 3, the heat pipe 200 may be directly connected to the internal surface of the bottom of the first half housing 110. The capillary structure 130 may be disposed in different configurations according to different manufacturing procedures of the capillary structure 130. Please refer to FIG. 4, the capillary structure 130 may be connected between the internal surface of the bottom of the first half housing 120 and the heat pipe 200. Please refer to FIG. 5 and FIG. 6, the capillary structure 130 may further cover an outer surface of the heat pipe 200, in other words, the capillary structure 130 covers the heat absorbing segment 210.

While this disclosure has been described by means of specific embodiments, numerous modifications and variations could be made thereto by those skilled in the art without departing from the scope and spirit of this disclosure set forth in the claims.

What is claimed is:

1. A heat dissipation module, comprising:
a heat conductive housing, comprising a first half housing and a second half housing, wherein the first half housing and the second half housing are coupled with each other, a capillary structure is attached to an internal surface of the heat conductive housing, and a working fluid is filled in the heat conductive housing; and
at least one heat pipe, penetrating through the heat conductive housing, wherein the heat pipe is attached to an internal surface of the first half housing on a bottom.

2. The heat dissipation module according to claim 1, wherein the first half housing comprises a pair of first edge notches correspondingly disposed on an edge of an opening thereof, and the heat pipe is embedded in the pair of first edge notches to penetrate through the first half housing.

3. The heat dissipation module according to claim 1, wherein the second half housing comprises a pair of second edge notches correspondingly disposed on an edge of an opening thereof, and the heat pipe is embedded in the pair of second edge notches to penetrate through the second half housing.

4. The heat dissipation module according to claim 1, wherein the capillary structure covers an outer surface of the heat pipe.

5. The heat dissipation module according to claim 1, wherein the heat pipe comprises a heat absorbing segment, accommodated in the heat conductive housing, and transversal cross-sectional area of the heat absorbing segment is smaller than transversal cross-sectional areas of other segments of the heat pipe.

6. The heat dissipation module according to claim 5, wherein the capillary structure covers the heat absorbing segment.

7. The heat dissipation module according to claim 5, wherein the heat absorbing segment is in a flat shape, and one surface of the heat absorbing segment is attached to the internal surface of the first half housing.

8. The heat dissipation module according to claim 5, wherein a plurality of heat conductive columns are disposed in the heat conductive housing, two ends of each of the heat conductive columns are connected to the internal surface of the first half housing and an internal surface of the second half housing.

9. The heat dissipation module according to claim 8, wherein the plurality of heat conductive columns and the heat absorbing segment are separately arranged.

10. The heat dissipation module according to claim 8, wherein the capillary structure covers an outer surface of each of the heat conductive columns.

11. The heat dissipation module according to claim 1, wherein the heat pipe is multiple in numbers and the heat pipes are disposed at intervals, a plurality of heat conductive columns are disposed in the heat conductive housing, two ends of each of the heat conductive columns are connected to the internal surface of the first half housing and an internal surface of the second half housing, and the plurality of heat conductive columns are disposed in intervals of the plurality of heat pipes.

12. The heat dissipation module according to claim 11, wherein the capillary structure covers an outer surface of each of the heat conductive columns.

13. The heat dissipation module according to claim 1, wherein the heat pipe and an internal surface of a bottom of the second half housing are separately arranged.

14. The heat dissipation module according to claim 1, wherein the heat pipe is attached to an internal surface of a bottom of the second half housing.
